(19) United States
(12) Patent Application Publication
(10) Pub. No.: US 2026/0112394 A1
(43) Pub. Date: Apr. 23, 2026

(54) CONTACT STRUCTURE FOR WORDLINES IN MEMORY CIRCUITS

(71) Applicant: Samsung Electronics Co., Ltd., Suwon-si (KR)

(72) Inventors: Maliha NOSHIN, San Jose, CA (US); Dongwan KIM, San Jose, CA (US); Young Doo JEONG, Campbell, CA (US)

(21) Appl. No.: 19/230,067

(22) Filed: Jun. 5, 2025

Related U.S. Application Data
(60) Provisional application No. 63/708,723, filed on Oct. 17, 2024.

(51) Int. Cl. G11C 5/06; H10D 64/66

(52) U.S. Cl. CPC G11C 5/063; H10D 64/665

(57) ABSTRACT

A system and a method for a contact structure are disclosed. The contact structure includes at least a first contact hole and a spacer. The first contact hole is filled with a metal material and having a first bottom end connected to a first wordline (WL) at a first contact point in a WL pad area of a memory circuit. The spacer surrounds the first contact hole at a location above the first contact point and is positioned on a second WL different from the first WL. The spacer is laterally recessed from the location.

### CROSS-REFERENCE TO RELATED APPLICATION

This application claims the priority benefit under 35 U.S.C. § 119(e) of U.S. Provisional Patent Application Serial No. 63/708,723 filed on October 17, 2024, the disclosure of which is incorporated by reference in its entirety as if fully set forth herein.

### TECHNICAL FIELD

The disclosure generally relates to memory devices. More particularly, the subject matter disclosed herein relates to contact structure for wordlines in memory circuits.

### BACKGROUND

The present background section is intended to provide context only, and the disclosure of any concept in this section does not constitute an admission that said concept is prior art.

Three-dimensional (3-D) memory configurations have been increasingly popular. 3-D memory devices, such as vertically stacked dynamic random access memory (VSDRAM) and vertical NAND (V-NAND) flash memory, include memory cells that are stacked vertically to increase storage density. One feature of 3-D memory circuits is the arrangement of control lines in a staircase structure. The staircase is employed to form the electrical connection between the control gate and contact. However, when the number of layers increases, the usable area for the memory channel decreases. In addition, structural support for a large number of layers may present problems. Accordingly, staircase-free designs aim at removing the staircase configuration while maintaining the same level of desired density. One particular feature of staircase-free memory circuits is the use of spacers for isolation.

Existing techniques for designing spacers in staircase-free memory circuits, however, face several challenges, especially for high aspect ratio memory circuits. First, conformal deposition of spacers is difficult. Second, etching towards the bottom of the contact is hard to control. Third, etching may cause damage or defects in sidewalls of the contact.

The above information disclosed in this Background section is only for enhancement of understanding of the background of the disclosure and therefore it may contain information that does not constitute prior art.

### SUMMARY

To overcome these issues, systems and methods are described herein for a technique of providing a staircase-free contact structure for WLs in a three-dimensional (3-D) memory device. In some embodiments, the contact structure includes at least a first contact hole and a spacer. The first contact hole is filled with metal and having a first bottom end connected to a first WL at a first contact point in a WL pad area of a memory circuit. The spacer surrounds the first contact hole at a location above the first contact point and is positioned on a second WL different from the first WL. The spacer is laterally recessed from the location.

In some embodiments, the contact structure further includes a second contact hole filled with metal and having a second bottom end connected to a third WL at a second contact point in the WL pad area. The third WL is at top of the WL pad area and there is no spacer surrounding the second contact hole. The first and second contact holes are substantially parallel to each other and perpendicular to the WLs.

### BRIEF DESCRIPTION OF THE DRAWINGS

In the following section, the aspects of the subject matter disclosed herein will be described with reference to exemplary embodiments illustrated in the figures, in which:

FIG. 1 is a block diagram illustrating a system that utilizes a 3-D memory circuit according to an embodiment.

FIG. 2 is a diagram illustrating a 3-D memory circuit that utilizes a contact structure according to an embodiment.

FIG. 3 is a diagram illustrating a sideview of the contact structure having a laterally recessed spacer according to an embodiment.

FIG. 4A is a diagram illustrating the first four stages of the manufacturing process of the contact structure according to an embodiment.

FIG. 4B is a diagram illustrating the last two stages of the manufacturing process of the contact structure according to an embodiment.

FIG. 4C is a diagram illustrating the additional stage of replacing silicon with metal at the WL of the manufacturing process of the contact structure according to one embodiment.

FIG. 5 is a diagram illustrating large spacers for capacitance reduction according to an embodiment.

FIG. 6 is a diagram illustrating a comparison between laterally recessed spacers and conformally deposited spacers according to an embodiment.

FIG. 7A is a flow chart illustrating a first part of a process of manufacturing the contact structure for a memory circuit according to an embodiment.

FIG. 7B is a flow chart illustrating a second part of a process of manufacturing the contact structure for a memory circuit according to an embodiment.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms and a plural term may include the corresponding singular form. It is further noted that various figures(including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Many applications, especially applications in Artificial Intelligence (AI) and signal processing, require a vast storage capacity and high throughput computations. To satisfy these needs, highly dense memory circuits in 3-D configuration are developed. In the following, systems and methods are described for a technique of providing a contact structure for WL in a memory circuit. One disclosed embodiment is a staircase-free contact structure for a three-dimensional (3-D) memory device. The contact structure includes at least a first contact hole and a spacer. The first contact hole is filled with metal and having a first bottom end connected to a first WL at a first contact point in a WL pad area of a memory circuit. The spacer surrounds the first contact hole at a location above the first contact point and is positioned on a second WL different from the first WL. The spacer is laterally recessed from the location.

Along the contact hole filled with metal, spacers are positioned only on WLs. Accordingly, the fabrication process is simple to control without the need of conformal deposition of spacer material outside the contact hole. In addition, the process may include etching vertically at the bottom end to form a connection or contact with the WL and avoiding sidewall etching. The technique is flexible, allowing large spacer areas to reduce negative effects of capacitances in the WL pad are. The techniques is especially advantageous for high aspect ratio vertically stacked memory circuits.

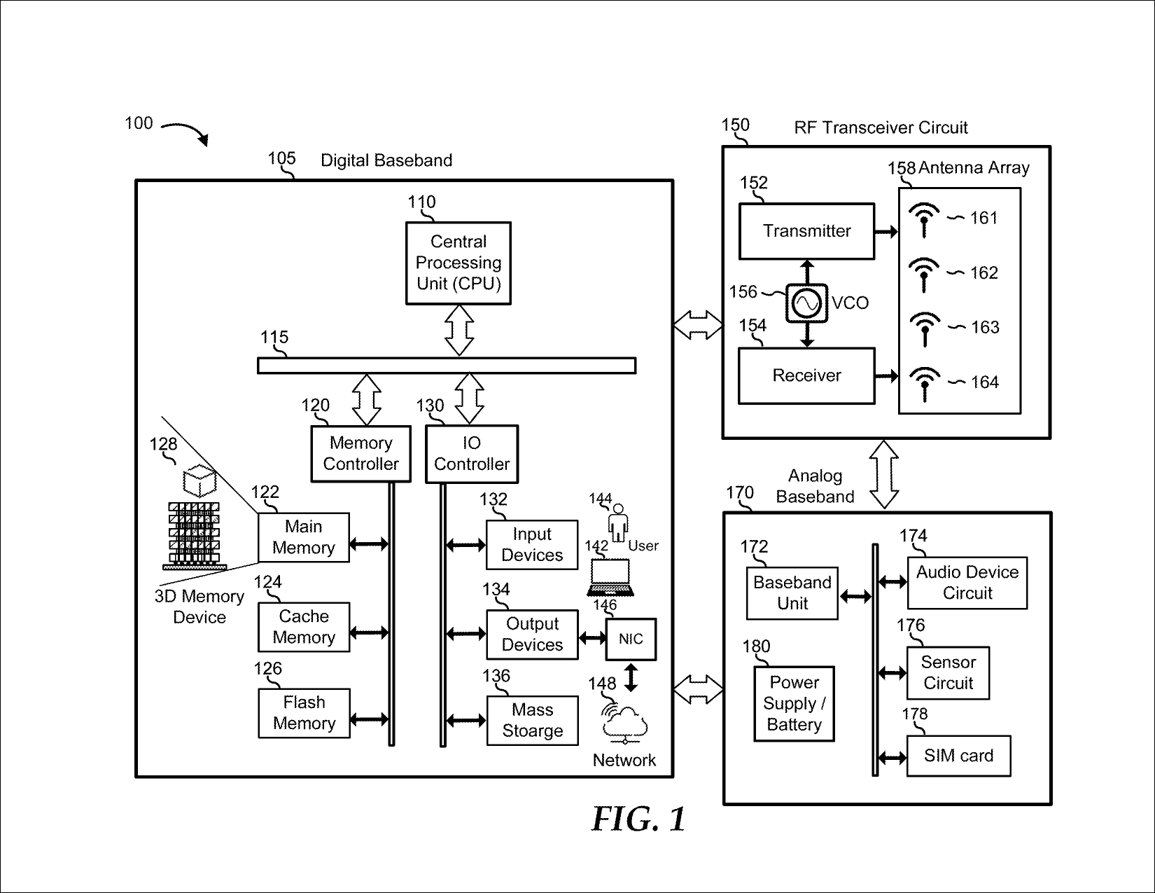

FIG. 1 is a block diagram illustrating a system that utilizes a 3-D memory circuit according to an embodiment. The system 100 includes a digital baseband circuit 105, a radio frequency (RF) transceiver circuit 150, and an analog baseband circuit 170. The system 100 may represent a digital system or a mobile system. When the system 100 is used as a digital system without mobile circuitry, the RF transceiver circuit 160, and the analog baseband circuit 190 are not used. In addition, when the system 100 is used as a mobile device, many of the digital devices are scaled back and some devices may not be available.

The digital baseband circuit 105 includes central processing unit (CPU) 110, a memory controller 120, and an IO controller 130. The system 100 may include more or less than the above components. In addition, a component may be integrated into another component. The integration may be partial and/or overlapped. For example, the memory controller 120 and the I/O controller 130 may be integrated into one single controller.

The CPU 110 is a programmable device that may execute a program or a collection of instructions to carry out a task. It may be a host that controls or manages other processors or devices. In particular, the CPU 110 may include applications programming interfaces (APIs), applications, or drivers that are executed by the CPU 110 to perform specified tasks. The CPU 110 may be a general-purpose processor, a digital signal processor, a microcontroller, or a specially designed processor. It may include a single core or multiple cores. Each core may have multi-way multi-threading. The CPU 110 may have simultaneous multithreading feature to further exploit the parallelism due to multiple threads across the multiple cores. In addition, the CPU 110 may have internal caches at multiple levels. The CPU 110 communicates with other devices in the system via a bus 115. The bus 115 may be any suitable bus connecting the CPU 110 to other devices. For example, the bus 115 may be a Direct Media Interface (DMI). The bus 115 may also include other custom buses such as bus for the interface to the analog section when the system 100 is used as a mobile device.

The memory controller 120 controls memory devices such as a main memory 122, a cache memory 124, and a flash memory 126. The main memory 122 includes random access memory (RAM) including static RAM (SRAM) and dynamic RAM (DRAM) and/or the read-only memory (ROM) and other types of memory. The DRAM may include Synchronous DRAM (SDRAM), Double Data Rate SDRAM (DDR SDRAM) with variations (e.g., DDR2, DDR3, DDR4, DDR5, and DDR6). The main memory 122 may store instructions or programs, loaded from a mass storage device, that, when executed by the CPU 110, cause the CPU 110 to perform operations for a specified task. It may also store data used in the operations. The ROM may be a solid-state drive (SSD) and include instructions, programs, constants, or data that are maintained whether it is powered or not. The instructions or programs may correspond to the functionalities described in the following. In one embodiment, the main memory 122 includes a 3-D memory device or circuit 128 such as VSDRAM and V-NAND flash memory, or any other memory devices that have memory cells that are stacked vertically to increase storage density

The I/O controller 130 controls input devices 132, output devices 134, and mass storage 136. The input devices 132 may include a keyboard, a mouse, an image sensor or camera, a game console, and a microphone. Other input devices may also be available such as stylus, joystick, scanner, and light pen. The input devices may also have a user interface to interface to a computer or laptop 142 and/or a user 144. The output devices 134 may include a printer, a monitor or screen, a headset, and a multi-monitor set. When used as a computing device without mobile features, the monitor is a high-resolution display. For games and other multi-display mode, the multi-monitor set provides high-resolution with multiple monitors (e.g., three monitors). When used for mobile communication, the screen provides the primary interface for the user to navigate, access various applications and perform tasks. The screen may use organic light-emitting diode (OLED) (super retina) display with multi-touch or haptic touch feature. The mass storage 136 may include CD-ROM, hard disk, and solid-state drives (SSDs). The I/O controller 130 also has a network interface card (NIC) 145 which provides an interface to a network and wireless medium 148.

Additional devices or bus interfaces may be available for interconnections and/or expansion. Some examples may include the Peripheral Component Interconnect Express (PCIe) bus, the Universal Serial Bus (USB), etc.

The RF transceiver circuit 150 includes a transmitter 152, an antenna array 158, a voltage-controlled oscillator (VCO) 156, and a receiver 154. The RF circuit 150 operates at a high GHz frequency band to accommodate modern cellular equipment such as the wireless fifth generation (5G).

The transmitter 152 transmits the digital baseband data to the antenna array 158. The transmitter 152 may include a digital-to-analog converter (DAC), an automatic gain controller (AGC), an intermediate frequency (IF) circuit, a mixer, an RF circuit, and a power amplifier (PA). Other components may include filters, amplifiers, multiplexers, coaxial cables, phase shifters, etc. The DAC converts digital data f₁ into an analog signal f₂. The AGC automatically adjusts the signal amplitude of f₂ to generate a signal f₃ to maintain a consistent strength level in a dynamic and changing environment. The IF circuit performs intermediate frequency processes such as filtering to generate a signal f₄. The mixer converts the frequency of the signal f₄ to another frequency. This is done by mixing the signal f₄ with a signal vₜ from the VCO 156. Mixing here refers to frequency modulation which translates the signal f₄ to a signal f₅ at a different frequency. For transmitter, the translated frequency is higher than the frequency of f₄. The conversion is called up-conversion. For 5G communication, the frequency range may include low-band (below 1 GHz), mid-band (1 GHz to 6 GHz), and high-band (24 GHz to 53 GHz or higher). The resulting signal f₅ then goes through various radio frequency processes performed by the RF circuit such as high-pass filtering to produce a signal f₆. The signal f₆ is strengthened and amplified by the PA to produce a signal f₇. The signal f₇ then goes to the antenna array 158 to be transmitted to an appropriate destination and medium (e.g., base station). The antenna array 158 uses beam forming to focus radio waves from f₇ in a desired direction. The antenna array 158 may be used for both transmitting and receiving. On receiving, the antenna array 158 receives an RF signal and sends it to the receiver 154. The number of antennas in the antenna array 158 depends on the desired coverage. The antenna array 158 may include antennas 161, 162, 163, and 164 configured to operate with 5G communication, Gigabit Long Term Evolution (LTE), Wi-Fi (e.g., 2.4 GHz, 5 GHz, and 6Ghz), and Bluetooth, respectively. The number of antennas may be more or less than the above.

The VCO 156 couples multiple in-phase oscillators together to provide low phase noise oscillation. It generates signals vₜ and vᵣ to the mixers at specified frequencies. It may include multiple oscillation core circuits (or VCO cores) to provide high-frequency periodic signals.

The receiver 154 processes the received signal r₇ in a manner reverse from the transmitter 152. It may include a low noise amplifier (LNA), an RF circuit, a mixer, an IF circuit, an AGC, and an analog-to-digital converter (ADC). The receiver 154 may include more or less than the above components. The LNA amplifies the weak signal r₇ while maintaining a good signal-to-noise ratio (SNR) to produce a signal r₆ for further processing. The signal r₆ is next processed by the RF circuit such as band-pass filtering to provide a signal r₅. Additional filtering may be performed in the next stages. The signal r₅ is then mixed with the signal vᵣ from the VCO 161 to down convert the signal r₅ to a signal r₄ at an appropriate low frequency. Like the mixer in the transmitter 152 but with a reverse operation, the mixer in the receiver performs frequency modulation to translate the high frequency signal r₅ to a low frequency signal r₄. The signal r₄ goes through IF processing such as additional filtering by the IF circuit to produce a signal r₃. The AGC amplifies and strengthens the signal and generates a signal r₂. The ADC converts the analog signal r₂ into digital data r₁ which will be processed by the CPU 110.

The analog baseband circuit 170 provides analog processing for various components. It handles processing of signals and data between the digital baseband circuit and the RF transceiver circuit 150. It may include analog and digital components to perform various tasks including modulation/demodulation, controlling the RF transceiver circuit 150, special circuitry for 3G, 4G/LTE, Bluetooth, and 5G communication. It may also interface with an audio device circuit 174, a sensor circuit 176, a Subscriber Identity Module (SIM) card 178, and other components. The audio device circuit 174 may include operational blocks to process audio signals and perform audio-related functions such as filtering, correlation, speech recognition. It may include digital circuits to perform Fast Fourier Transform (FFT) to perform signal processing in the frequency domain. The sensor circuit 176 may include a variety of sensors such as proximity, ambient light, motion (accelerometer and gyroscope, compass, barometer, fingerprint sensor for touch identification (ID), image sensors for face ID, light detection and ranging (LiDAR) scanner, etc. The SIM card 178 is a small, removable chip that stores the user’s phone number and carrier information, allowing the device to connect to a cellular network.

The power supply and battery circuit 180 provides power and battery backup supply to the entire system. It may include a charger to charge the battery. The battery may be a rechargeable battery, of Lithium-Ion battery. Power management may be performed by application software and circuits to provide low power mode and performance management.

The system 100 is an example that illustrates the role of 3-D memory devices in a laptop, desktop or mobile environment. In many cases, the environment of the applications adds additional requirements including low power consumption, reliable signal integrity, fault-tolerance, and reliable operations in extreme conditions including heat and tight space. Examples of other applications that would benefit from 3-D memory devices or circuits include mobile communication (e.g., smart phones, base stations, user equipment), cameras, vehicles, entertainment (e.g., games, multimedia, music, movies), technical designs (e.g., animation, graphics), medical (e.g., visualization, medical imaging), robotics, drones, automatic test equipment, audio processing, speech synthesizer, video and image analysis, vision, automatic face recognition, artificial intelligence (AI) applications, and data centers.

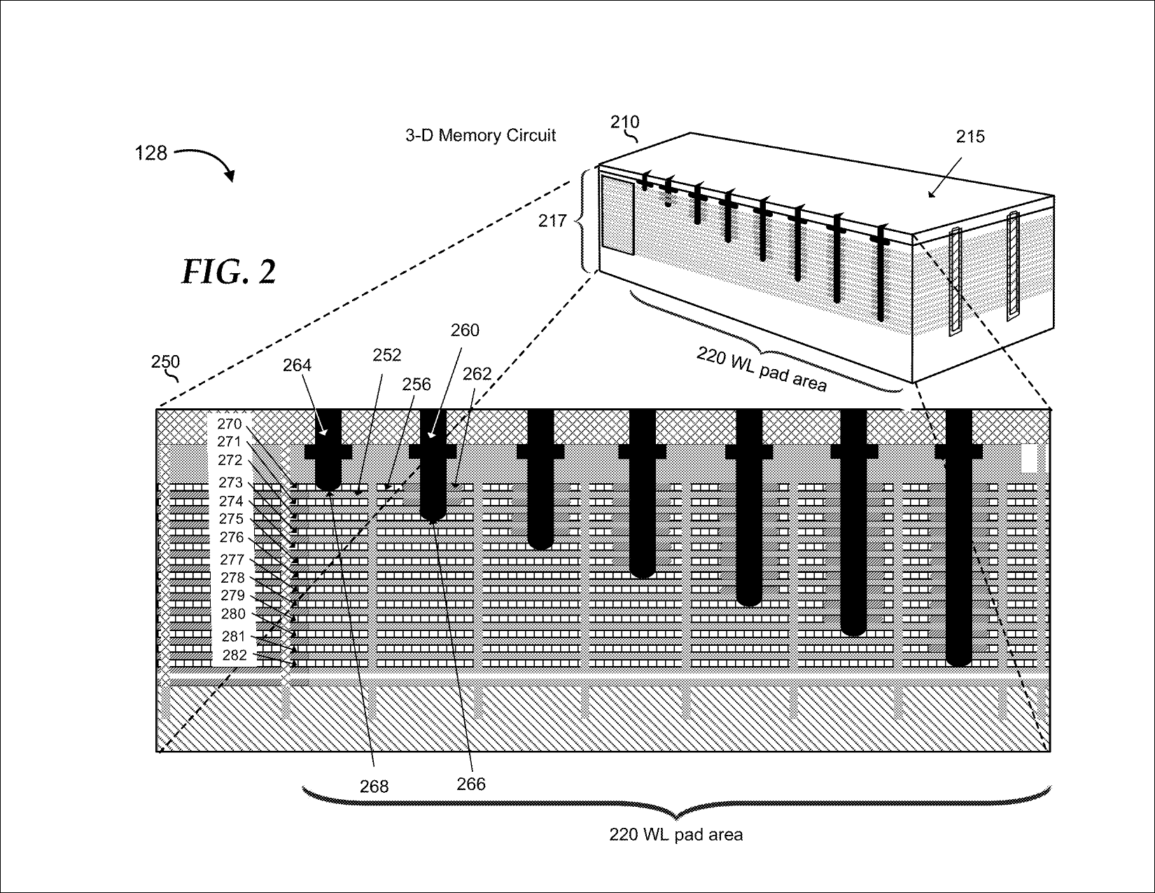

FIG. 2 is a diagram illustrating the 3-D memory circuit 128 shown in FIG. 1 that utilizes a contact structure according to an embodiment. The 3-D memory circuit 128 includes a substrate or a region 217. The substrate 217 has a surface 215 and a wordline (WL) pad area 220. For illustrative purposes, the substrate/region 217 is shown in 3-D. The sideview 250 of the substrate/region 217 shows the contact structure in the WL pad area 220 in two-dimensional (2-D).

The sideview 250 shows a contact 260 with a spacer 262 and a contact with no spacer 264 in the WL pad area 220. The contacts 260 and 264 are contacts to WLs in the 3-D memory circuit 128. Both contacts have a similar structure except the length and the depth of immersion or penetration into the WL pad area 220. Each contact has a bottom end which is designed to contact, or is connected to, the WL. The WL pad area 220 includes alternating strips of different materials characterized by a first strip 252 and a second strip 256. In one embodiment, the first strip 252 is a dielectric or oxide such as silicon oxide (SiO₂). The second strip 256 is metal such as titanium nitride (TiN) or tungsten (W). The second strip 256 corresponds to a WL in the memory circuit. The WL pad area 220 illustratively shows the second strips representing WLs 270, 271, 272, 273, 274, 275, 276, 277, 278, 279, 280, 281, and 282. These WLs are separated by strips like the first strip 252. The second strip 256 coincides with the WL 270. In general, the WLs 270, 271, 272, 273, 274, 275, 276, 277, 278, 279, 280, 281, and 282 are parallel in a horizontal direction. The contacts 260 and 264 are perpendicular to the WLs.

The contact 260 has laterally recessed spacers represented by a spacer 262. The spacer 262 surrounds the contact 260 at the WL 270 on the second strip 256 to isolate the area of the contact 260 at that location from the WL 270. In one embodiment, the spacer 262 is made of a dielectric such as silicon nitride (SiN). In general, a spacer surrounds the contact when the contact may be in contact with the WLs. When the bottom end of a contact makes contact or touches a WL at a contact point, no spacer is used so that such a contact can be made. For example, the bottom end of the contact 260 touches the WL 272 at a contact point 266. There is no spacer on the WL 272 at the contact point 266. Similarly, the bottom end of the contact 264 touches the WL 270 at a contact point 268. There is no spacer on the WL 270 at the contact point 268. Furthermore, since the contact 264 does not penetrate into the WL pad area 220 past WL 270 at the top, it does not have any spacer at all because it has no potential contact with any WL.

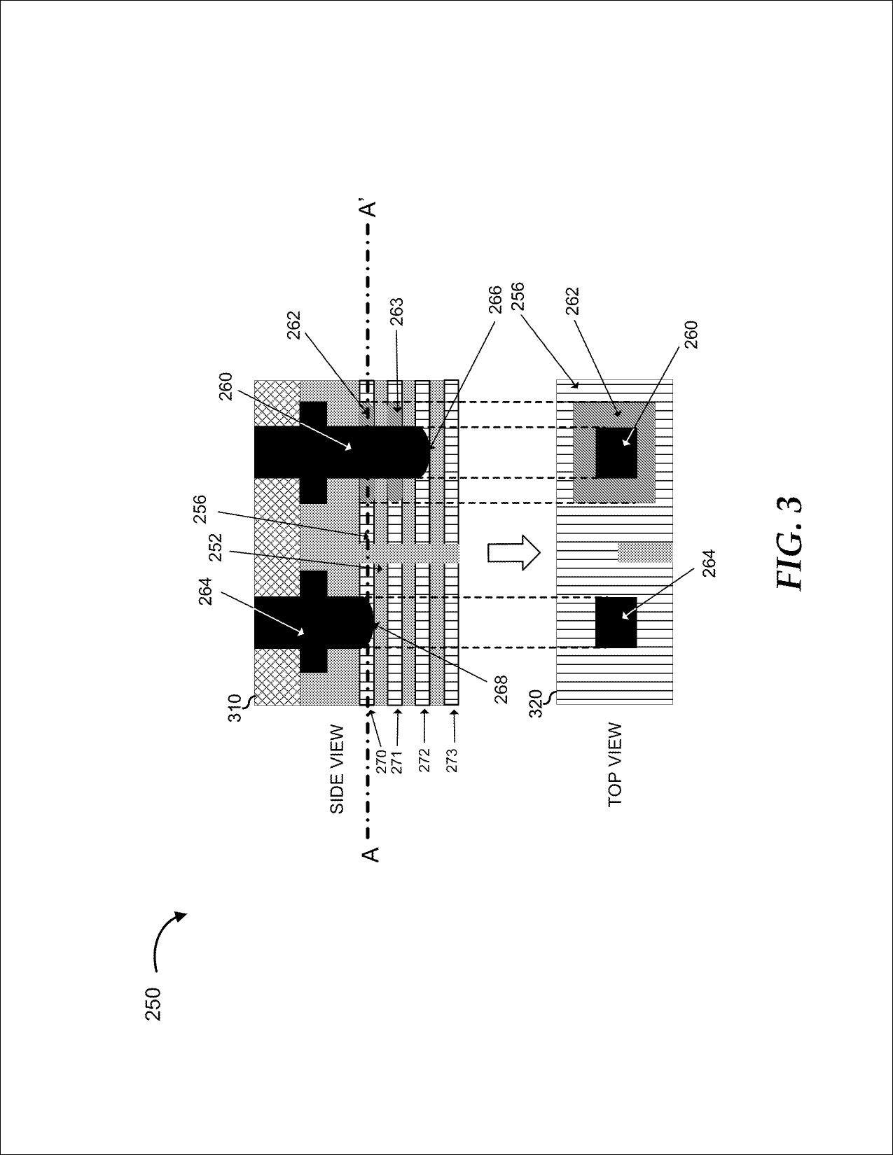

FIG. 3 is a diagram illustrating the sideview 250 of the contact structure having a laterally recessed spacer according to an embodiment. The sideview 250 includes a view 310 and a view 320. The view 310 shows the contact 260 and 264 as shown in FIG. 2 in sideview. The contact 260 makes contact with, or is connected to, the WL 272 at the contact point 266. The contact 264 makes contact with the WL 270 at the contact point 268.

The view 320 is the top view of the view 310 at the line AA’. The line AA’ runs through the WL 270, crossing the tip of the bottom end of the contact 264 and the laterally recessed spacer 262 and the body or the core of the contact 260. From the top view, the contact 264 has a cross section that looks like a square which represents the contact hole. The square shape is only for illustration. Any shape (e.g., circle, ellipse) is appropriate depending on the geometry of the etching process that form the contact hole. Similarly, from the top view, the contact 260 has a cross-section that looks like a square within another square. The smaller square represents the cross section of the core of the contact 260. The larger square represents the spacer 262 that surrounds the body of the contact 260. Again, the square shape of the spacer 262 on the top view is for illustration only. Its shape may be the same or different from the shape of the contact 260 depending on the etching process. In addition, the spacer only surrounds the contact at the intersection area between the contact and the WL. As shown in view 310, the spacers 262 and 263 surround the core 260 on the WLs 270 and 271, respectively. There are no spacers between the WLs.

The laterally recessed spacer may be described in relative to the contact point 266. In essence, the laterally recessed spacer is positioned on a WL that is above the WL that is connected to the bottom end of the contact hole. The contact structure includes at least a first contact hole 260 and at least a spacer 262. The first contact hole 260 is filled with metal and having a first bottom end 266 connected to a first WL 272 at a first contact point 266 in the WL pad area 220 of the memory circuit 210. The spacer 262 or 263 surrounds the first contact hole 260 at a location above the first contact point 266 and is positioned on a second WL 270 or 271 different from the first WL 272. The spacer is laterally recessed from the location.

The contact structure further includes a second contact hole 264 filled with metal and having a second bottom end connected to a third WL 270 at a second contact point 268 in the WL pad area 220. The third WL 270 is at top of the WL pad area 220 and there is no spacer surrounding the second contact hole 264. The third WL may be the same as the WL having the spacer 262 around the contact 260 (i.e., WL 270) or may be different as the WL having the spacer 263 around the contact 260. (i.e., WL 271). The first and second contact holes 260 and 264 are substantially parallel to each other and perpendicular to the WLs 270, 271, 272, and 273.

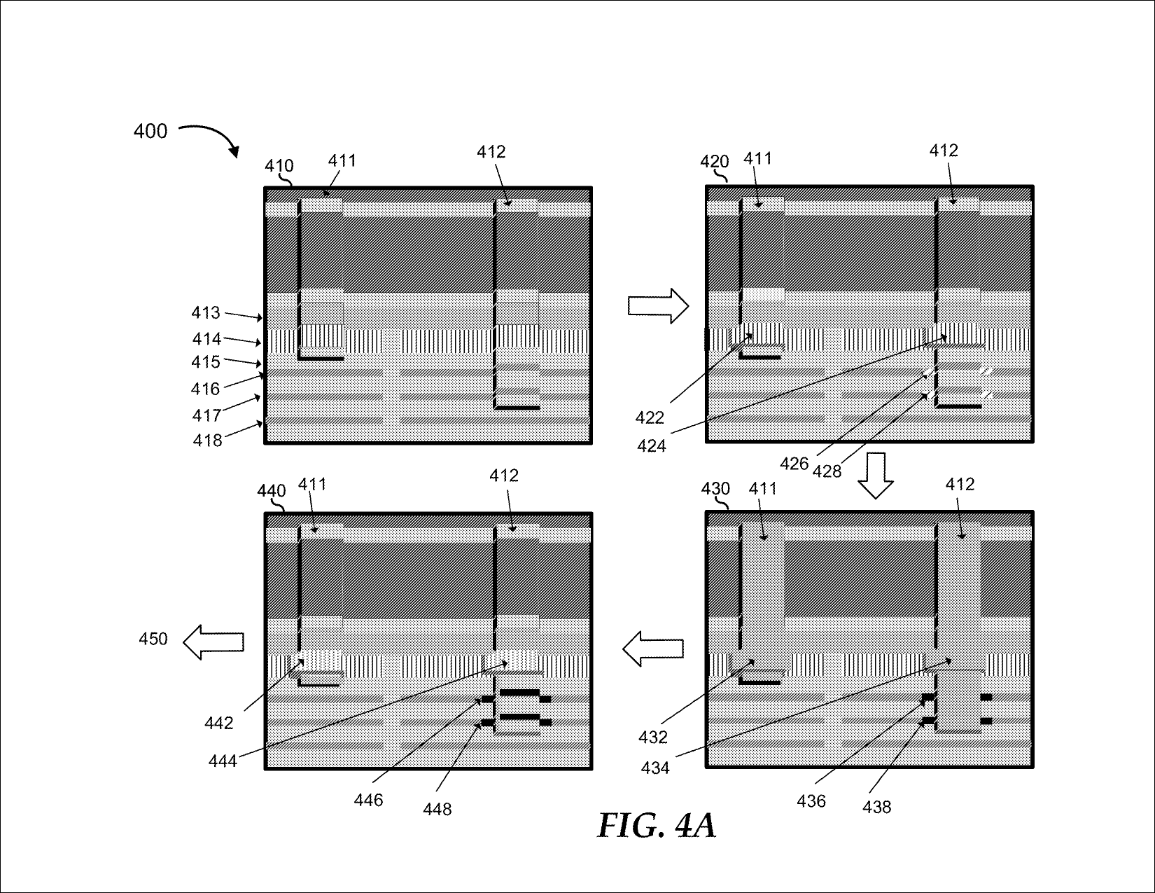

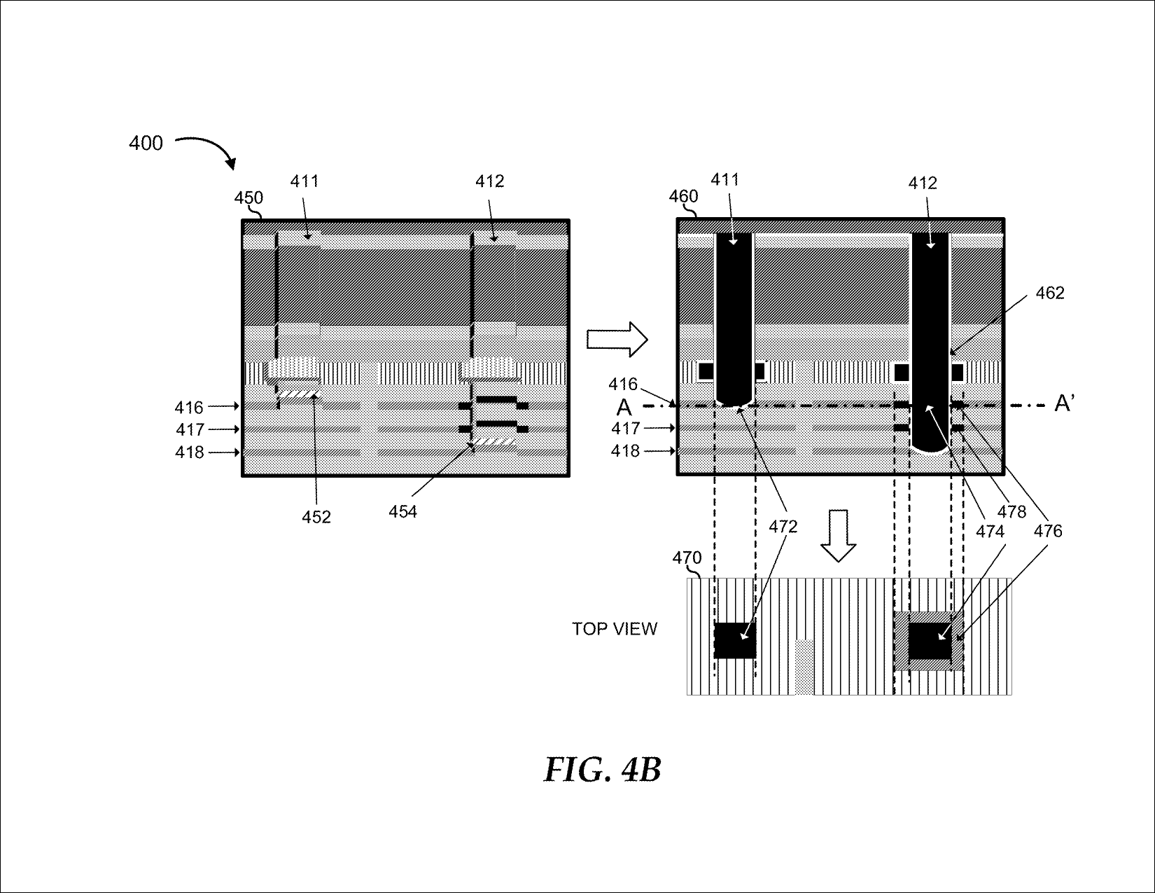

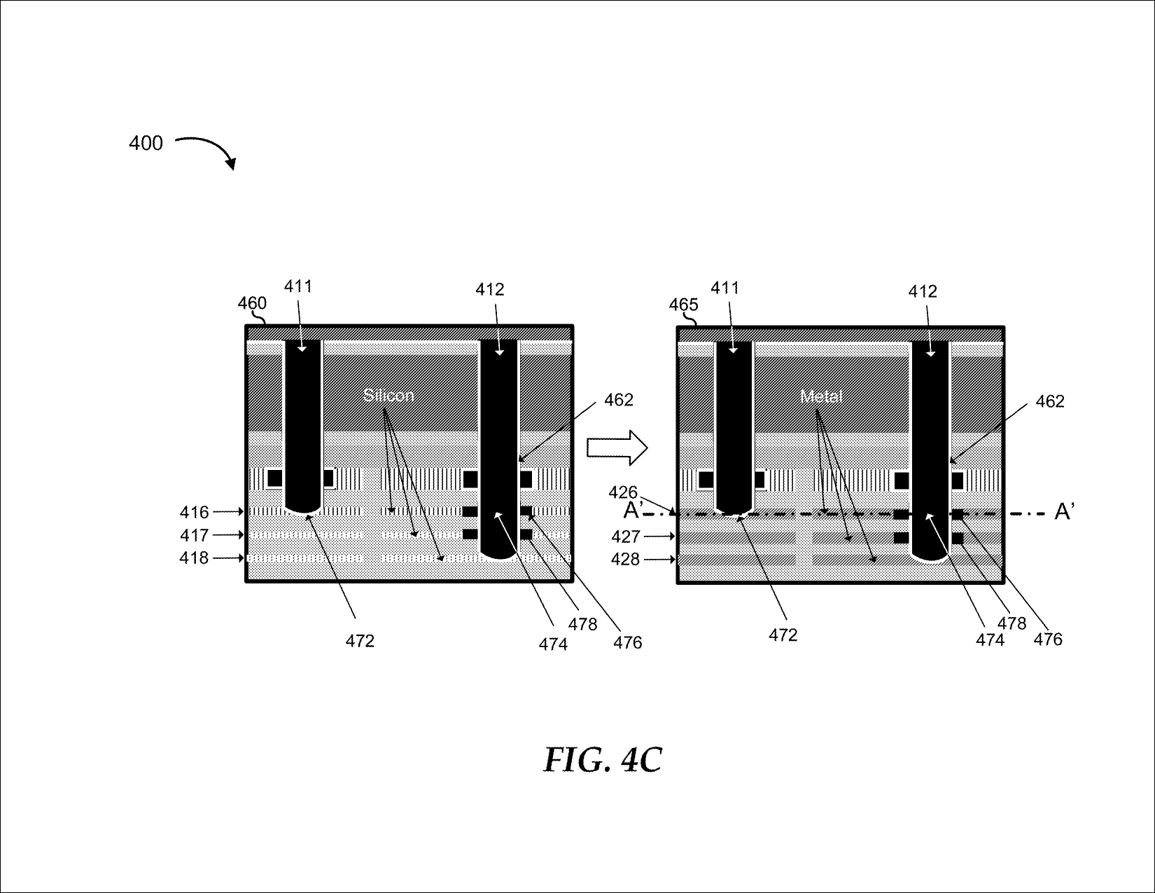

FIG. 4A is a diagram illustrating the first four stages of the manufacturing process 400 of the contact structure according to an embodiment. The first four stages of the process 400 includes stages 410, 420, 430, and 440. For illustrative purposes, various parts of the layers or components in each stage are shown with shades and patterns mainly for visual effects. These shades and patterns do not have any electrical meanings.

The stage 410 is the initial stage to form contact holes 411 and 412. This may be carried out by a through cell metal contact (TCMC) process. In addition, high aspect ratio contact (HARC) etching helps creating deep and narrow holes in a multilayer stack of materials. The contact holes 411 and 412 are formed on layers or strips 413, 414, 415, 416, 417, and 418. The layer/strip 413 is any suitable layer. In one embodiment, it is a dielectric such as silicon nitride. The layer/strip 414 is a silicon layer. The layer/strip 415 and other layers with the same shade are represented as first strips. In one embodiment, the first strip is an oxide. The layer/strip 416, 417 and 418 are represented as the second strips. The area below the layer/strip 414 includes alternating layers or strips of the first type and the second type, or alternating first strips and second strips. The second strips are positioned at the WLs. While the first strip 415 may be an oxide, there may be two choices for the second strip 416 at this stage. In one embodiment, the second strip is silicon. In another embodiment, the second strip is metal. Whether it is silicon or metal, the following stages are the same except for the last stage. For the last stage, if the second strips 416, 417, and 418 are initially metal in stage 410, then the process stops. If the second strips 416, 417, and 418 are initially silicon, then the last stage includes replacing the silicon by metal.

The stage 420 is to etch the lateral recesses at the second strips. The etching is performed on the silicon strip 414 and the second strips 416 and 416, resulting in the etched recesses 422, 424, 426, and 428. In particular, the recesses 426 and 428 are lateral and coincide with the WLs 416 and 417, respectively.

The stage 430 is for deposition of spacer material into the contact hole and the etched lateral recesses. In one embodiment, the spacer material is silicon nitride (SiN). The contact holes are filled with spacer material such as at locations 432, 434, 436 and 438. The lateral recesses 436 and 438 are now deposited with spacer material.

The stage 440 is for spacer trimming. In this stage, the spacer material is removed or trimmed throughout the contact except at the lateral recesses 446 and 448. The next stage is stage 450 shown in FIG. 4B.

FIG. 4B is a diagram illustrating the last two stages of the manufacturing process 400 of the contact structure according to an embodiment. These last two stages include stage 450 and stage 460. As mentioned earlier, if at stage 410, the strips 416, 417, and 418 are metal, then stage 460 is the last stage. If the strips 416, 417, and 418 are silicon, then after stage 460, there will be an additional stage in which the silicon strips corresponding to the WLs are replaced by metal. This is shown in FIG. 4C.

The stage 450 is for making contact at the bottom end. The bottom end of each contact is punched or vertically etched with chemical etchant to make contact with, or connect to, the WL. The bottom end 452 of the contact 411 will be vertically etched to make contact with the second strip 416. Similarly, the bottom end 454 of the contact 412 will be vertically etched to make contact with the second strip 418.

The stage 460 is for deposition of metal into the contact holes 411 and 412. In one embodiment, the metal is titanium nitride (TiN) or tungsten (W). Any other metal materials (e.g., gold) may be used depending on the requirements and/or manufacturing criterial or preferences. The metal is separated from the lateral recesses 476 and 478 by sidewalls inside the contacts, such as sidewall 462.

The stage 460 shows the sideview. A top view 470 may be seen at the cross-section line AA’. The top view 470 is similar to the top view 320 in FIG. 3. The line AA’ crosses the bottom end of the contact 411 and the lateral recess 476. Viewed from the top, the cross section of the contact 411 is a square 472. As discussed in FIG. 3, any other shape of the cross-section may be possible depending on the etching geometry. For the contact 412, the top view shows a square 474 surrounded by a larger square 476. The larger square 476 is the lateral recess.

FIG. 4C is a diagram illustrating the additional stage of replacing silicon with metal at the WL of the manufacturing process 400 of the contact structure according to one embodiment. As discussed above, if the strips 416, 417, and 418 are silicon, then after stage 460, there will be an additional stage in which the silicon strips corresponding to the WLs are replaced by metal. The additional stage is a stage 465.

The stage 460 is the same as the stage 460 in FIG. 4B except that the strips 416, 417, and 418 are not metal. Instead, they are silicon. In the stage 465, the silicon strips 416, 417, and 418 are etched to remove silicon and create empty spaces. Then, a metal material is deposited in the empty spaces to create metal strips 426, 427, and 428, respectively. A top view may be seen at the cross-section line AA’ similar to the top view 470 in FIG. 4B and will not be repeated here.

Since spacers are dielectric, they are useful for filtering. For noise filtering, low capacitances are effective for high frequency signals. Since memory addressing typically involves high frequency signaling, it is preferable to have a circuit that can lower stray or parasitic capacitances. The spacers by virtue of their being dielectric can help lower the circuit capacitances. A larger spacer tends to lower the capacitance.

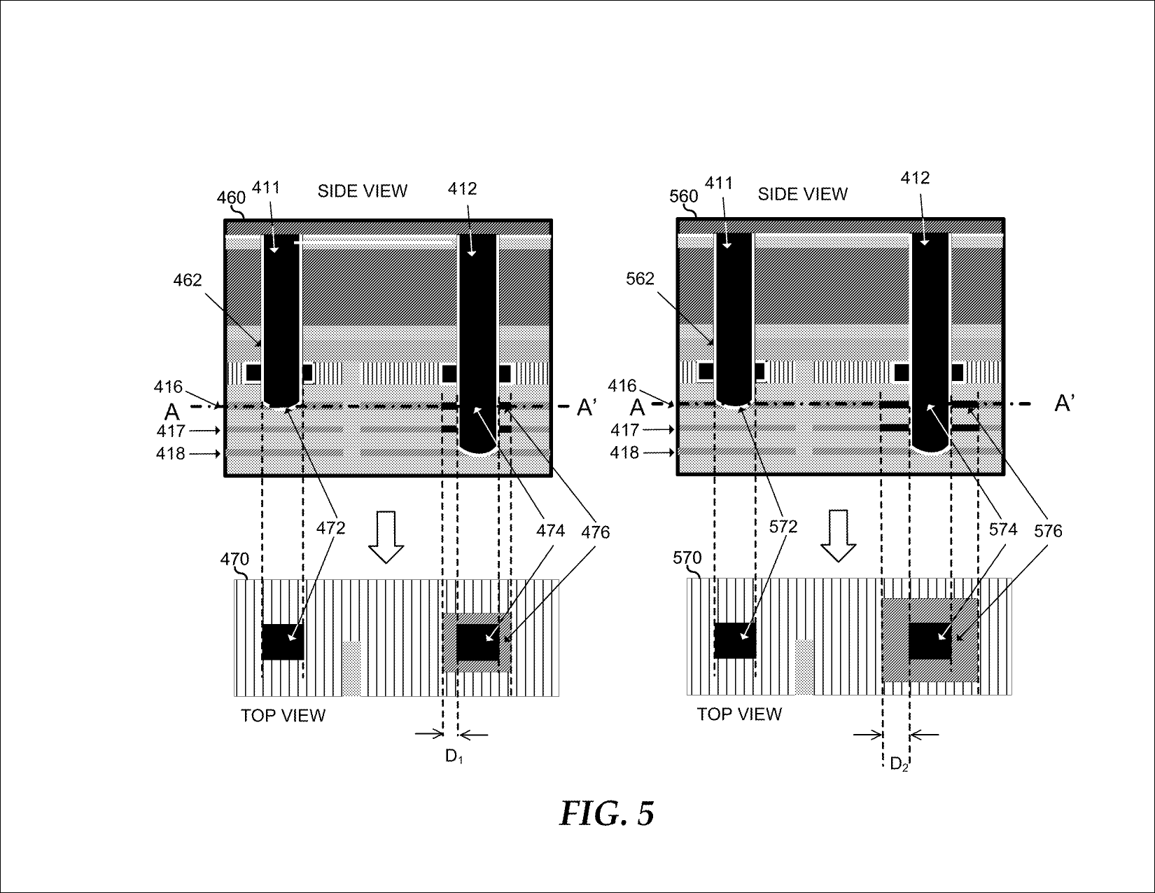

FIG. 5 is a diagram illustrating large spacers for capacitance reduction according to an embodiment. A sideview 560 is placed next to the sideview 460 in FIG. 4A for comparison. The contact structure in the sideview 560 is similar to that in the sideview 460 except that the lateral spacers are larger. A line AA’ crosses the WL 416 as in the sideview 460 to show a top view 570. The AA’ crosses the bottom end 572 of the contact hole 411 and the spacer 576 of the contact hole 412.

The top view 570 shows the cross section of the contact hole 411 as a square 472 as in the top view 470. It also shows the cross section of the contact hole 412 as a square 574. The cross section of the spacer 572 is a square 576 surrounding the square 574. Since the spacer 576 is larger than the spacer 476, its cross section is larger than the cross section of the spacer 476. The width D₂ of the lateral spacer 576 is larger than the width D₁ of the lateral spacer 476. The result is a larger dielectric area which results in lower capacitances in the WL pad area 220.

The size of the spacers along the contact hole 412 and other contact holes can be easily controlled by etching an appropriate amount without the need of conformal deposition of the spacer material. This feature facilitates the manufacturing process and results in effective spacer configuration for isolation of contacts to the WLs.

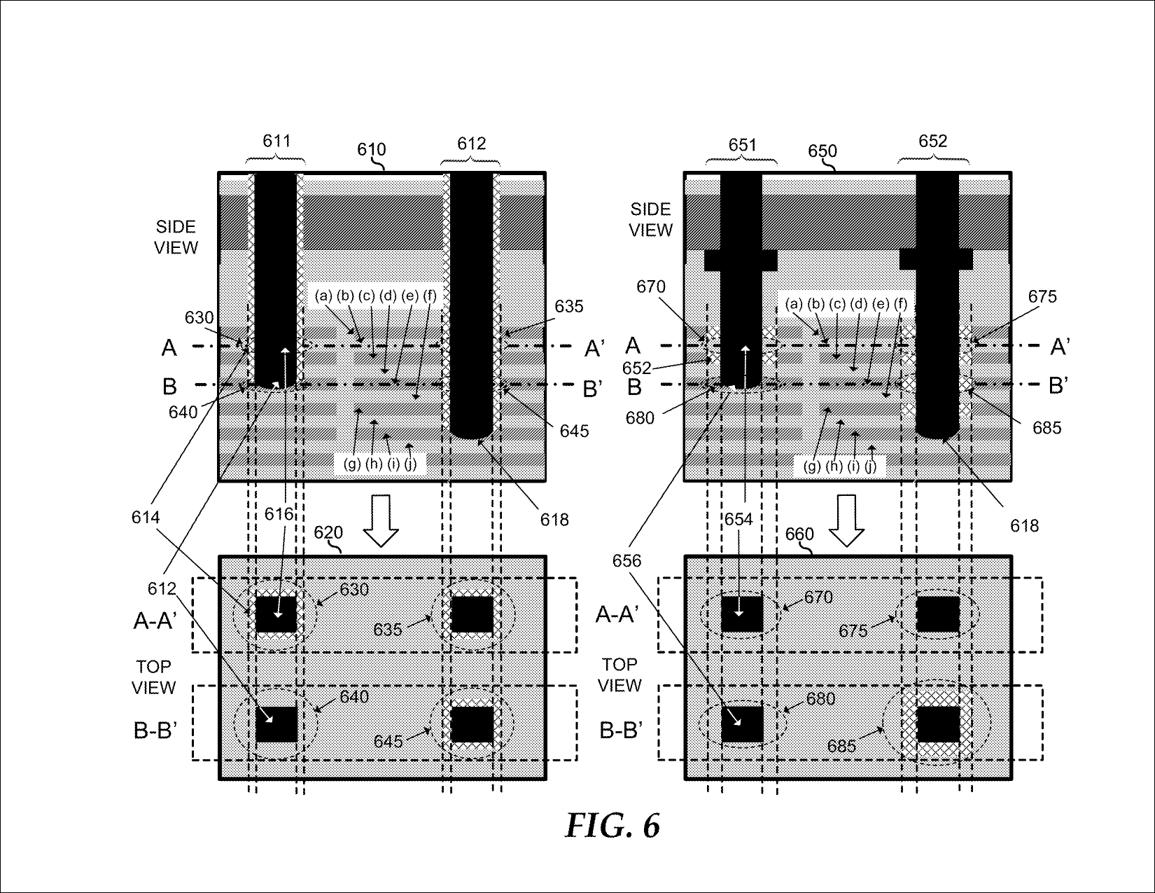

FIG. 6 is a diagram illustrating a comparison between conformally deposited spacers and laterally recessed spacers according to an embodiment. The conformally deposited spacers are shown in a sideview 610 and a top view 620. The laterally recessed spacers are shown in a sideview 650 and a top view 660. For clarity, not all parts are labeled.

The side view 610 shows the WL pad area having alternate strips or layers of WLs and oxides. The WLs are (a), (c), (e), (g), and (i). The oxide strips or layers are (b), (d), (f), (h), and (j). There are two contacts 611 and 612. Each contact has spacer covered for the entire length except at the bottom. The contact 611 is connected to the WL (e) at a bottom end 612. The contact 612 is connected to the WL (i) at a bottom end 618.

Two lines AA’ and BB’ cross the sideview 610 to show the cross-section in the top view 620. The line AA’ runs through the oxide layer (b). It crosses the contact 611 at an area 630 and the contact 612 at an area 635. The line BB’ runs through the WL (e). It crosses the contact 611 at an area 640 and the contact 612 at an area 645. The top view 620 shows the cross-sections corresponding to line AA’ on top and line BB’ at the bottom. The cross-section AA’ has the area 630 and 635. The area 630 includes a square 614 surrounding a square 616. As mentioned earlier, the square shape is only for illustration. Any shape according to the etching geometry may be used. The outer square 614 shows the surrounding spacer even though the line AA’ crosses an oxide layer/strip and not a WL. This is because the spacer covers the entire length of the contact 611. Similarly, the area 635 includes an outer square surrounding an inner square. The outer square shows the surrounding spacer even though the line AA’ crosses an oxide layer/strip and not a WL. For clarity, not all parts are labeled. The cross-section BB’ has the area 640 and 645. The area 640 includes only a square 612 corresponding to the bottom end. Since this is the bottom end at the contact point, there is no spacer. The area 645 has an outer square corresponding to the spacer and an inner square corresponding to the core of the contact 612. For clarity, not all parts are labeled.

The views for the laterally recessed spacers include a sideview 650 and a top view 660. The side view 650 shows the WL pad area having alternate strips or layers of WLs and oxides similar to the side view 610. The WLs are (a), (c), (e), (g), and (i). The oxide strips or layers are (b), (d), (f), (h), and (j). There are two contacts 651 and 652. Each contact has spacer covered along the length of the contact only at the WLs. The bottom end has no spacer because it is the contact point with the WL. The contact 651 is connected to the WL (e) at a bottom end 656. The contact 652 is connected to the WL (i) at a bottom end 658.

Like in the sideview 610, two lines AA’ and BB’ cross the sideview 650 to show the cross-section in the top view 660. The line AA’ runs through the oxide layer (b). It crosses the contact 651 at an area 670 and the contact 652 at an area 675. The line BB’ runs through the WL (e). It crosses the contact 651 at an area 680 and the contact 652 at an area 685. The top view 660 shows the cross sections corresponding to line AA’ on top and line BB’ at the bottom. The cross-section AA’ has the area 670 and 675. The area 670 includes only a square 654 corresponding to the core of the contact 651. As mentioned earlier, the square shape is only for illustration. Any shape according to the etching geometry may be used. Since the line AA’ crosses an oxide layer/strip and not a WL, there is no spacer. This is because the spacer is laterally recessed only on WL. This is contrast to the configuration using the conformally deposited spacers shown in sideview 610. Similarly, the area 675 has only one square corresponding to the core of the contact 652. The cross-section BB’ has the areas 680 and 685. The area 680 includes only a square 656 corresponding to the bottom end. Since this is the bottom end at the contact point, there is no spacer. The area 685 has an outer square corresponding to the spacer and an inner square corresponding to the core of the contact 652. For clarity, not all parts are labeled.

Compared to the conformally deposited spacers, the laterally recessed spacers are much simpler and provide an efficient manufacturing process. The spacers are not wasted on layers or strips that do not need isolation.

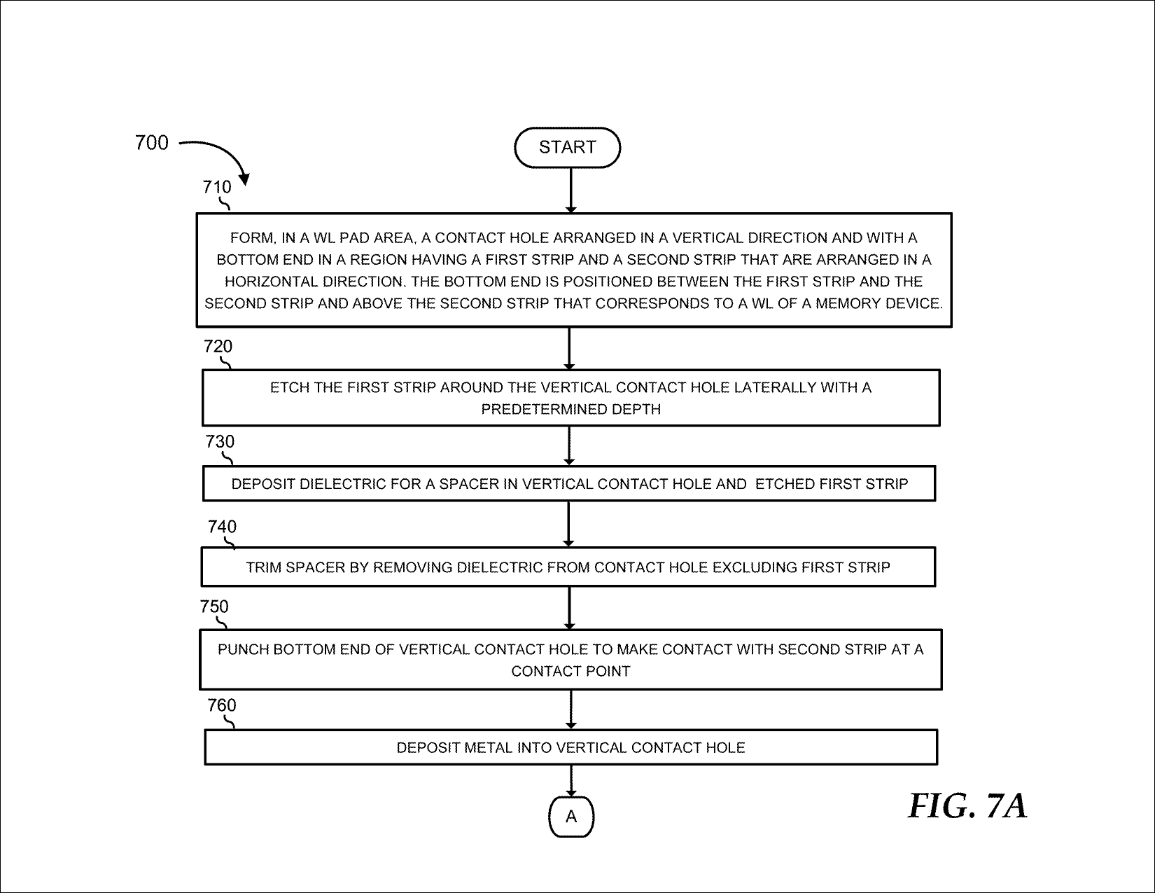

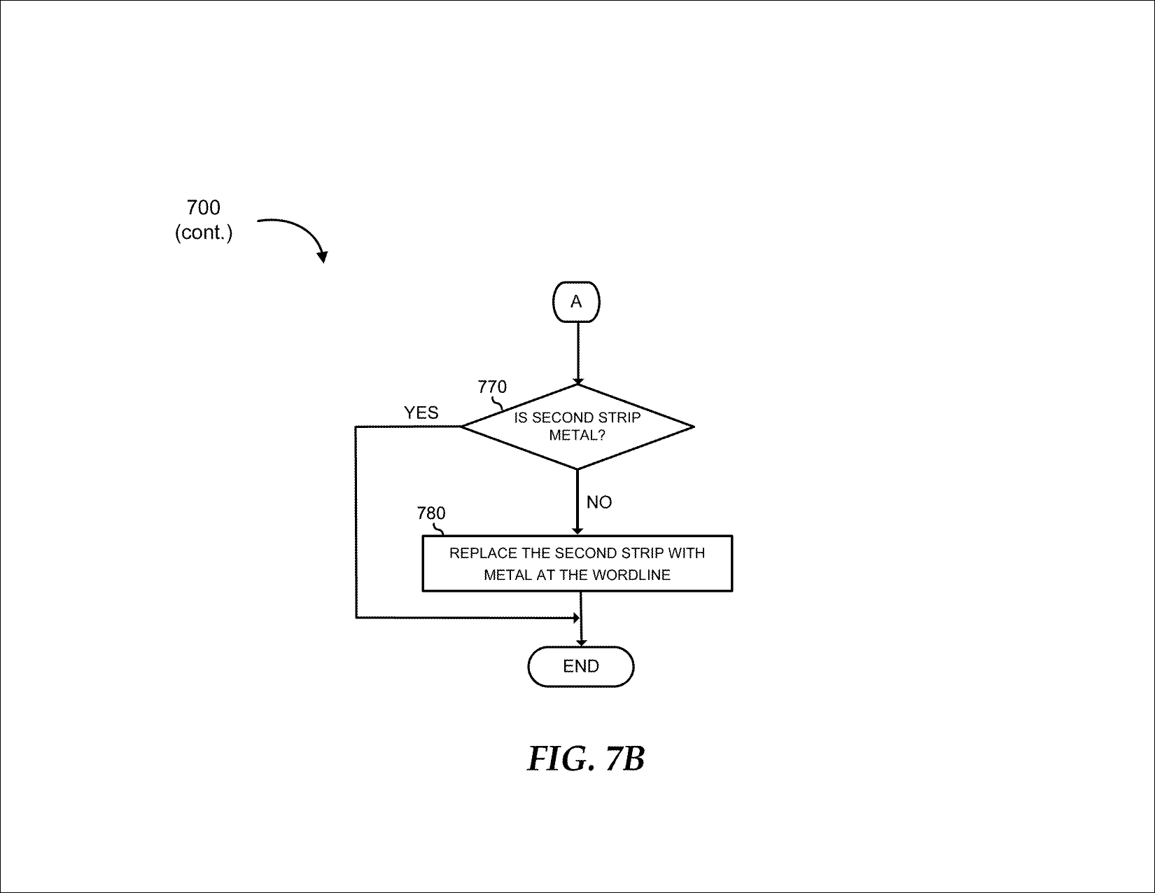

FIG. 7A is a flow chart illustrating a first part of a process 700 of manufacturing the contact structure for a memory circuit according to an embodiment. The process 700 follows the manufacturing or fabrication steps described in FIGS. 4A and 4B. The use of first strip and second strip in the description is for brevity and clarity. The process is applied to all WLs and other layers including the oxide and silicon layers in the WL pad area.

Upon START, the process 700 forms in a WL pad area a contact hole arranged in a vertical direction and with a bottom end in a region having a first strip and a second strip (Block 710). This step corresponds to stage 410 in FIG. 4A. As mentioned above, the use of first and second strips are for clarity and brevity. The process is performed with other suitable strips in the WL pad area. The first strip and the second strip are arranged in a horizontal direction. The bottom end of the vertical contact hole is positioned between the first strip and the second strip and above the second strip that corresponds to a WL of a memory device. For illustrative purposes, the first strip and the second strip may correspond to the WLs 417 and 418, respectively, in FIG. 4A

Then, the process 700 etches the first strip around the vertical contact hole laterally with a predetermined depth (Block 720). This step corresponds to stage 420 in FIG. 4A. Next, the process 700 deposits dielectric for a spacer in the vertical contact hole and the etched first strip (Block 730). This step corresponds to the stage 430 in FIG. 4A.

Next, the process 700 trims the spacer by removing the dielectric from the vertical contact hole excluding the first strip (Block 740). This step corresponds to the stage 440 in FIG. 4A. Then, the process 700 punches the bottom end of the vertical contact hole to make contact with the second strip at a contact point (Block 750). This step corresponds to the stage 450 in FIG. 4B. Next, the process 700 deposits metal into the vertical contact hole (Block 760). This step corresponds to the stage 460 in FIG. 4B. The process 700 then continues to continuation block A in FIG. 4B.

FIG. 7B is a flow chart illustrating a second part of a process of manufacturing the contact structure for a memory circuit according to an embodiment. The second part starts from point A. From the start point A, the process 700 determines if the second strip is metal (Block 770). As mentioned in the description of FIGS. 4A and 4B, the initial stage may or may not have metal at the WLs. If the second strip is metal, indicating that the WLs have been deposited with metal, the process 700 is terminated. Otherwise (NO at block 770), the process 700 replaces the second strip with metal at the WL (Block 780). This stage may be performed with the WL padding process as shown in FIG. 4C. The process 700 is then terminated.

Embodiments of the subject matter and the operations described in this specification may be implemented in digital electronic circuitry, or in computer software, firmware, or hardware, including the structures disclosed in this specification and their structural equivalents, or in combinations of one or more of them. Embodiments of the subject matter described in this specification may be implemented as one or more computer programs, i.e., one or more modules of computer-program instructions, encoded on computer-storage medium for execution by, or to control the operation of data-processing apparatus. Alternatively, or additionally, the program instructions can be encoded on an artificially-generated propagated signal, e.g., a machine-generated electrical, optical, or electromagnetic signal, which is generated to encode information for transmission to suitable receiver apparatus for execution by a data processing apparatus. A computer-storage medium can be, or be included in, a computer-readable storage device, a computer-readable storage substrate, a random or serial-access memory array or device, or a combination thereof. Moreover, while a computer-storage medium is not a propagated signal, a computer-storage medium may be a source or destination of computer-program instructions encoded in an artificially-generated propagated signal. The computer-storage medium can also be, or be included in, one or more separate physical components or media (e.g., multiple CDs, disks, or other storage devices). Additionally, the operations described in this specification may be implemented as operations performed by a data-processing apparatus on data stored on one or more computer-readable storage devices or received from other sources.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable sub-combination. Moreover, although features may be described above as acting in certain combinations and even initially claimed as such, one or more features from a claimed combination may in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims.

What is claimed is:

1. A device comprising:
a first contact hole filled with a metal material and having a first bottom end connected to a first wordline (WL) at a first contact point in a WL pad area of a memory circuit; and
a spacer surrounding the first contact hole at a location above the first contact point and positioned on a second WL different from the first WL,
wherein the spacer is laterally recessed from the location.

2. The device of claim 1, wherein the first WL and the second WL are parallel.

3. The device of claim 1, wherein the first contact hole is substantially perpendicular to the first WL.

4. The device of claim 1, wherein the metal material comprises at least one of titanium nitride (TiN), tungsten (W), or gold (Au).

5. The device of claim 1, wherein the spacer has a width within a predetermined range to reduce capacitance in the WL pad area.

6. The device of claim 1, wherein the first contact hole is elongated from surface of the WL pad area to the contact point.

7. The device of claim 1, wherein the first WL and the second WL are separated by an oxide layer.

8. The device of claim 1, further comprising:
a second contact hole filled with a metal material and having a second bottom end connected to a third WL at a second contact point in the WL pad area.

9. The device of claim 1, wherein the third WL is at top of the WL pad area.

10. The device of claim 1, wherein the memory circuit is organized in a three-dimensional (3D) structure.

11. A method comprising:
forming, in a wordline (WL) pad area, a contact hole arranged in a first direction and with a bottom end in a region having a first strip and a second strip that are arranged in a second direction, the bottom end of the contact hole being positioned between the first strip and the second strip and above the second strip that corresponds to a WL of a memory device;
etching the first strip around the contact hole laterally with a predetermined depth.
depositing a dielectric material for a spacer in the contact hole and the etched first strip;
trimming the spacer by removing the dielectric material from the contact hole while the dielectric material remains in the etched first strip;
punching the bottom end of the contact hole to make contact with the second strip at a contact point; and
depositing a metal material into the contact hole.

12. The method of claim 11, wherein the first strip includes an oxide and the second strip includes at least one of polysilicon or metal.

13. The method of claim 11, wherein the metal material includes at least one of titanium nitride (TiN), tungsten (W), or gold (Au).

14. The method of claim 11, further comprising:
replacing the second strip with the metal material at the WL.

15. The method of claim 11, wherein punching the bottom end of the contact hole comprises etching in the first direction with a chemical etchant.

16. The method of claim 11, wherein the predetermined depth of the spacer corresponds to a desired reduction of capacitance.

17. The method of claim 11, wherein the contact hole is elongated from surface of the WL pad area to the contact point.

18. The method of claim 11, wherein the first strip and the second strip are adjacent in the first direction.

19. The method of claim 11, wherein the contact hole is substantially perpendicular to one of the first strip or the second strip.

20. A system comprising:
a memory circuit comprising:
a wordline (WL) pad area for contacts with WLs having at least a first WL and a second WL; and
a contact structure comprising:
a first contact hole filled with metal and having a first bottom end connected to the first WL at a first contact point; and
a spacer surrounding the first contact hole at a location above the first contact point and positioned on a second WL different from the first WL,
wherein the spacer is laterally recessed from the location.
